(19) United States
(12) Patent Application Publication
(10) Pub. No.: US 2025/0308853 A1
(43) Pub. Date: Oct. 2, 2025

(54) METHOD OF MANUFACTURING POWER SEMICONDUCTOR ELEMENT

(71) Applicant: JUSUNG ENGINEERING CO., LTD., Gwangju-Si, Gyeonggi-Do (KR)

(72) Inventor: Chul Joo HWANG, Gwangju-Si, Gyeonggi-Do (KR)

(21) Appl. No.: 18/569,210

(22) PCT Filed: Jun. 10, 2022
(86) PCT No.: PCT/KR2022/008227

§ 371 Date: Jul. 15, 2024

(30) Foreign Application Priority Data
Jun. 11, 2021 (KR) 10-2021-0076037
Jun. 9, 2022 (KR) 10-2022-0070241

(51) Int. Cl. H01J 37/32; C23C 16/44; C23C 16/455; H01L 21/02

(52) U.S. Cl. CPC H01J 37/32449; C23C 16/4408; C23C 16/45534; C23C 16/45542; H01L 21/02378; H01L 21/02576; H01L 21/02579; H01L 21/0262; H01J 2237/332

(57) ABSTRACT

Provided is a method for manufacturing a power semiconductor device, which includes forming an active layer including a first active layer and a second active layer, which are doped with impurities different from each other, on an SiC substrate. The forming of the active layer includes preparing the SiC substrate comprising a first area and a second area, sequentially injecting a source gas mixed with a first doping gas, a purge gas, a reactant gas, and a purge gas onto the first area of the SiC substrate to form the first active layer, and sequentially injecting a source gas mixed with a second doping gas, a purge gas, a reactant gas, and a purge gas onto the second area of the SiC substrate to form the second active layer. The second doping gas and the first doping gas include elements different from each other, respectively. Thus, in accordance with exemplary embodiments, the active layer may be formed at a low temperature. Thus, the substrate or the thin film formed on the substrate may be prevented from being damaged by the high-temperature heat. In addition, the power or time required for heating the substrate to form the active layer may be saved, and the overall process time may be shortened. In addition, the active layer may be crystallized to be formed. That is, the crystallized active layer may be formed while forming the active layer at the low temperature.

### TECHNICAL FIELD

The present disclosure relates to a method for manufacturing a power semiconductor device, and more particularly, to a method for manufacturing a power semiconductor device, in which an active layer is formed through an atomic layer deposition method.

### BACKGROUND ART

A field effect transistor includes an active layer formed on a substrate, source and drain electrodes formed above the active layer, a gate electrode formed to be disposed between the source electrode and the drain electrode above the active layer, and a well region provided between the source electrode, the drain electrode, and the active layer.

The active layer is formed by a metal organic chemical vapor deposition (MOCVD) method. Here, a thin film is deposited to deposit the active layer in a state in which the substrate is adjusted to a high temperature of approximately 1,200° C. That is, when the substrate is maintained at a high temperature of approximately 1,200° C., the active layer may be deposited on the substrate.

However, as the active layer is formed while the substrate is heated to the high-temperature, there is a limitation in that the substrate or the thin film formed on the substrate is damaged. In addition, this acts as a factor that deteriorates a function of the field effect transistor or causes a defect. Particularly, when the field effect transistor is used for power conversion or control of an electronic device, the damage caused when the active layer is formed at the high temperature becomes a factor that significantly degrades quality or function.

### RELATED ART DOCUMENT

### Related Art Document

### Patent Document

(patent document 1) Japanese Patent Registration No. 2571583

### DISCLOSURE OF THE INVENTIVE CONCEPT

### Technical Problem

The present disclosure provides a method for manufacturing a power semiconductor device that is capable of being manufactured at a low temperature.

The present disclosure also provides a method for manufacturing a power semiconductor device that is capable of forming an active layer at a low temperature.

### Technical Solution

In accordance with an exemplary embodiment, a method for manufacturing a power semiconductor device, which includes forming an active layer including a first active layer and a second active layer, which are doped with impurities different from each other, on an SiC substrate, wherein the forming of the active layer includes: preparing the SiC substrate comprising a first area and a second area; sequentially injecting a source gas mixed with a first doping gas, a purge gas, a reactant gas, and a purge gas onto the first area of the SiC substrate to form the first active layer; and sequentially injecting a source gas mixed with a second doping gas, a purge gas, a reactant gas, and a purge gas onto the second area of the SiC substrate to form the second active layer, wherein the second doping gas and the first doping gas include elements different from each other, respectively.

In accordance with another exemplary embodiment, a method for manufacturing a power semiconductor device, which includes forming an active layer including a first active layer and a second active layer, which are doped with impurities different from each other, on an SiC substrate, wherein the forming of the active layer includes: preparing the SiC substrate comprising a first area and a second area; sequentially injecting a source gas, a first doping gas, a purge gas, a reactant gas, and a purge gas onto the first area of the SiC substrate to form the first active layer; and sequentially injecting a source gas, a second doping gas, a purge gas, a reactant gas, and a purge gas onto the second area of the SiC substrate to form the second active layer, wherein the second doping gas and the first doping gas comprise elements different from each other, respectively.

The source gas may include one or two or more of Ga, In, Zn, and Si.

The reactant gas may include one or two or more of As, P, O, and C.

The forming of the first and second active layers may include repeatedly performing one process cycle, which is performed in order of the injection of the source gas, the injection of the purge gas, the injection of the reactant gas, and the injection of the purge gas.

The forming of the first active layer may include repeatedly performing one process cycle, which is performed in order of the injection of the source gas, the injection of the first doping gas, the injection of the purge gas, the injection of the reactant gas, and the injection of the purge gas, and the forming of the second active layer may include repeatedly performing one process cycle, which is performed in order of the injection of the source gas, the injection of the second doping gas, the injection of the purge gas, the injection of the reactant gas, and the injection of the purge gas.

The forming of the first and second active layers may include at least one of generating plasma after the injecting of the reactant gas or generating plasma between the injecting of the source gas and the injecting the reactant gas.

The generating of the plasma may include injecting a hydrogen gas.

The method may further include, before the forming of the first and second active layers, forming a crystalline buffer layer on the SiC substrate.

The buffer layer may be made of AIN.

One doping gas of the first and second doping gases may contain Mg, and the other doping gas may contain at least one of Si, In, Al, or Zn.

In accordance with yet another exemplary embodiment, a method for manufacturing a power semiconductor device includes: preparing an SiC substrate including a first area and a second area, wherein a first conductive type first active layer is formed on the first area; and sequentially injecting a source gas, a purge gas, a reactant gas, and a purge gas onto the second area to form a second conductive type second active layer, wherein the first conductive type and the second conductive type are different from each other and, and each of the first conductive type and the second conductive type comprises one of an n-type and a p-type.

The first active layer may be formed by sequentially injecting the source gas, the purge gas, the reactant gas, and the purge gas, and the source gas injected in the forming of the first and second active layers may include one or two or more of Ga, In, Zn, and Si.

The reactant gas injected in the forming of the first and second active layers may include one or two or more of As, P, O, and C.

### Advantageous Effects

In accordance with the exemplary embodiments, the active layer may be formed at the low temperature. Thus, the substrate or the thin film formed on the substrate may be prevented from being damaged by the high-temperature heat. In addition, the power or time required for heating the substrate to form the active layer may be saved, and the overall process time may be shortened.

In addition, the active layer may be crystallized to be formed. That is, the crystallized active layer may be formed while forming the active layer at the low temperature.

### BRIEF DESCRIPTION OF THE DRAWINGS

FIG. 1 is a conceptual view illustrating a substrate on which an active layer is formed through a method in accordance with an exemplary embodiment;

FIG. 2 is a cross-sectional view illustrating an example of a complementary metal oxide semiconductor device manufactured through the method in accordance with an exemplary embodiment;

FIG. 3 is a conceptual view for explaining a method for forming the active layer of the complementary metal oxide semiconductor device through the method in accordance with an exemplary embodiment.

FIG. 4 is a conceptual view illustrating a modified example in which a buffer layer is disposed between the active layer and the substrate;

FIG. 5 is a view illustrating an example of the complementary metal oxide semiconductor device in accordance with a modified example of the exemplary embodiment;

FIG. 6 is a schematic view illustrating a deposition device used in the method for manufacturing the power semiconductor device in accordance with an exemplary embodiment; and

FIG. 7 is a schematic view illustrating another example of the deposition device used in the method for manufacturing the power semiconductor device in accordance with an exemplary embodiment.

### MODE FOR CARRYING OUT THE INVENTIVE CONCEPT

Hereinafter, specific embodiments will be described in more detail with reference to the accompanying drawings. The present inventive concept may, however, be embodied in different forms and should not be construed as limited to the embodiments set forth herein. Rather, these embodiments are provided so that this disclosure will be thorough and complete, and will fully convey the scope of the present inventive concept to those skilled in the art. In the figures, the dimensions of layers and regions are exaggerated for clarity of illustration. Like reference numerals refer to like elements throughout.

An exemplary embodiment of the present disclosure relates to a method for manufacturing a power semiconductor device. In more detail, an exemplary embodiment of the present disclosure relates to a method for manufacturing a power semiconductor device, which includes a method for forming an active layer through an atomic layer deposition (ALD) method. More specifically, an exemplary embodiment of the present disclosure relates to a method for manufacturing a power semiconductor device, which includes a method for forming an n-type or p-type first active layer and a second active layer, which is provided in a type different from that of the first active layer, through an atomic layer deposition method. The power semiconductor device may be a device called a complementary metal oxide semiconductor (CMOS).

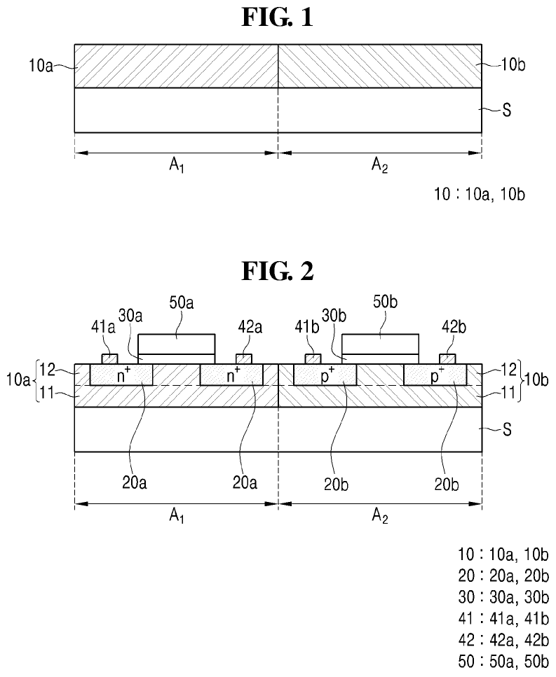

FIG. 1 is a conceptual view illustrating a substrate on which an active layer is formed through a method in accordance with an exemplary embodiment.

Referring to FIG. 1, the active layer 10 (10a and 10b) is a layer formed on a substrate S and may be an active layer constituting a power semiconductor device, more specifically, a complementary metal oxide semiconductor device. The active layer 10 may be formed through the atomic layer deposition (ALD) method. In addition, in the forming of the active layer 10 through the atomic layer deposition method, the active layer may be formed by generating plasma after stopping or finishing an injection of a reactant gas. Here, the active layer 10 may be formed by generating plasma using a hydrogen (H₂) gas (hereinafter, referred to as hydrogen plasma).

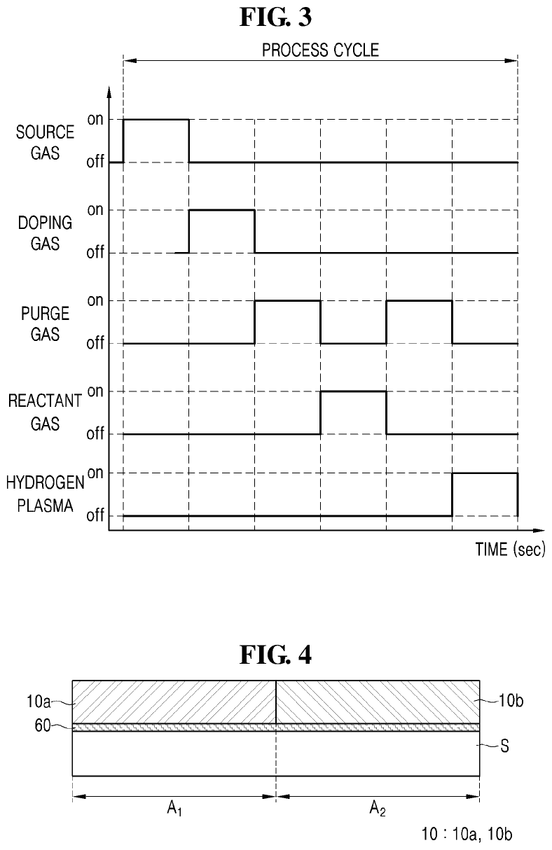

FIG. 2 is a cross-sectional view illustrating an example of a complementary metal oxide semiconductor device manufactured through the method in accordance with an exemplary embodiment. FIG. 3 is a conceptual view for explaining a method for forming the active layer of the complementary metal oxide semiconductor device through the method in accordance with an exemplary embodiment.

Hereinafter, a method of manufacturing the power semiconductor device including the active layer formed by the method in accordance with an exemplary embodiment will be described with reference to FIGS. 1 to 3. Here, the complementary metal oxide semiconductor device will be described as an example.

The complementary metal oxide semiconductor device manufactured through the method in accordance with an exemplary embodiment may include a substrate S, first and second active layers 10a and 10b disposed on different areas on the substrate S and having different types, a first source electrode 41a and a first drain electrode 42a, which are disposed to be horizontally spaced apart from each other above the first active layer 10a, a second source electrode 41b and a second drain electrode 42b, which are disposed to be horizontally spaced apart from each other above the second active layer 10b, a first gate electrode 50a disposed above the first active layer 10a and disposed between the first source electrode 41a and the first drain electrode 42a, a second gate electrode 50b disposed between the second source electrode 41b and the second drain electrode 42b above the second active layer 10b, first well layers 20a respectively disposed between the first source electrode 41a and the first active layer 10a and between the first drain electrode 42a and the first active layer 10a, second well layers 20b respectively disposed between the second source electrode 41b and the second active layer 10b and between the second drain electrode 42b and the second active layer 10b, a first gate insulating layer 30a disposed on the first active layer 10a to be disposed between the first source electrode 41a and the first drain electrode 42a, and a second gate insulating layer 30b disposed on the second active layer 10b so as to be disposed between the second source electrode 41b and the second drain electrode 42b.

Here, each of the first and second well layers 20a and 20b disposed to be in contact with the first and second source electrodes 41a and 41b or below the first and second source electrodes 41a and 41b may be a layer functioning as a source of the complementary metal oxide semiconductor. Here, each of the first and second well layers 20a and 20b disposed to be in contact with the first and second drain electrodes 42a and 42b or below the first and second drain electrodes 42a and 42b may be a layer functioning as a drain of the complementary metal oxide semiconductor.

The substrate S may be a substrate including silicon (Si) or a p-type substrate. More specifically, the substrate S may be a p-type SiC substrate.

A first active layer 10a and a second active layer 10b are disposed on the substrate S as illustrated in FIGS. 1 and 2. Here, the first active layer 10a and the second active layer 10b are disposed on different areas or different positions on a top surface of the substrate S. Hereinafter, for convenience of explanation, an area on which the first active layer 10a is disposed, on the top surface of the substrate S is referred to as a first area A1, and an area which is different from the first area A1 and on which the second active layer 10b is disposed is referred to as a second area A2.

Each of the first and second active layers 10a and 10b may be a layer or thin film made of any one of gallium arsenic (GaAs), indium phosphide (InP), aluminum gallium indium phosphide (AlGaInP), indium gallium zinc oxide (IGZO), indium zinc oxide (IZO), and silicon carbide (SiC). That is, each of the first and second active layers 10a and 10b may be provided as any one of a GaAs layer, an InP layer, an AlGaInP layer, an IGZO layer, an IZO layer, and a SiC layer.

Also, each of the first and second active layers 10a and 10b is provided in an n-type or a p-type, and the first active layer 10a and the second active layer 10b are provided in different types. For example, the first active layer 10a is provided in a p-type, the second active layer 10b is provided in an n-type. Alternatively, the first active layer 10a is provided in an n-type, and the second active layer 10b is provided in a p-type. In other words, the first active layer 10a and the second active layer 10b are provided in different conductivity types. That is, when the first active layer 10a is provided in a p-type first conductivity type, the second active layer 10b may be provided in an n-type second conductivity type. As another example, when the first active layer 10a is provided in an n-type second conductivity type, the second active layer 10b may be provided in a p-type first conductivity type.

Hereinafter, in description of the first and second active layers 10a and 10b, an example will be described, in which the first active layer 10a is provided in the p-type (first conductivity type), and the second active layer 10b is provided in the n-type (second conductivity type).

The first and second active layers 10a and 10b may be formed through an atomic layer deposition (ALD) method. In addition, in the forming of the active layer 10 through the atomic layer deposition method, the first and second active layers 10a and 10b may be formed by generating plasma after stopping or finishing an injection of an reactant gas. Here, the first and second active layers 10a and 10b may be formed by generating plasma using a hydrogen (H₂) gas (hereinafter, referred to as hydrogen plasma).

Hereinafter, a method of forming the first and second active layers 10a and 10b using the atomic layer deposition method will be described. Here, since doping materials of the first active layer 10a and the second active layer 10b are different from each other, and their formation methods are similar to each other, the first and second active layers 10a and 10b are collectively referred to an active layer 10 (10a and 10b), and thus, the formation method thereof will be described.

A process of forming the active layer 10 may include a process of injecting a source gas, a process of injecting a doping gas, a process of injecting a purge gas (primary purging), a process of injecting a reactant gas, and a process of injecting the purge gas (secondary purging). In addition, the process of forming the active layer 10 may include a process of generating plasma after the process of injecting the reactant gas. Here, the process of generating the plasma may be performed, for example, after the reactant gas is injected, and the secondary purging is finished. In this case, the injection of the source gas, the injection of the doping gas, the injection of the purge gas (primary purge), the injection of the reactant gas, the injection of the purge gas (secondary purging), and the generation of the plasma may be performed sequentially. In addition, the plasma generated after the secondary purging may be hydrogen plasma. That is, in the generation of the plasma after finishing the secondary purging, the plasma may be generated by injecting a hydrogen gas and discharging the hydrogen gas.

In addition, the plasma may be generated in the process of injecting the reactant gas. That is, the plasma may be generated by injecting the reactant gas and discharging the reactant gas.

In the forming of the active layer 10, ‘the injection of the source gas—the injection of the doping gas—the injection of the purge gas (primary purge)—the injection of the reactant gas—the injection of the purge gas (secondary purging)—the generation of the plasma’ as described above to form the active layer 10 may be defined as one process cycle. In addition, the above-described process cycle may be performed several times to perform the deposition of the atomic layer several times. In addition, the number of times of the process cycle to be performed may be adjusted to form the active layer 10 having a target thickness.

In the process cycle as described above, when the reactant gas is injected after the injection of the source gas, the injection of the doping gas, and the injection of the purge gas injection (primary purging), reaction between the source gas and the reactant gas occurs on the substrate S to generate a reactant, for example, AlGaInP. Then, the reactant is accumulated or deposited on the substrate S to form a thin film made of AlGaInP on the substrate S. In addition, a p-type AlGaInP thin film or an n-type AlGaInP thin film is formed in accordance with types of injected doping gases.

In the related art, in the deposition of the thin film to form the active layer on the substrate, the inside of the chamber or the substrate may be maintained at a high temperature of approximately 1,200° C. In other words, the thin film may be deposited on a top surface of the substrate only when the inside of the chamber or the substrate is maintained at the high temperature of approximately 1,200° C. When the active layer is formed at the high temperature, the substrate or the thin film formed on the substrate may be damaged, and the active layer may be damaged. Thus, there is a limitation in that a function or quality of the device is deteriorated.

However, in an exemplary embodiment, the plasma is generated in the depositing of the thin film using the atomic layer deposition method. That is, the plasma, for example, the hydrogen plasma is generated after the reactant gas is injected or after the injection of the reactant gas is finished. More specifically, after the reactant gas injection, and the injection of the purge gas (secondary purging) are finished, the plasma using the hydrogen gas is generated.

Here, the plasma may improve a reaction rate between the source gas and the reactant gas and may allow the reactant between the source gas and the reactant gas to be easily deposited or attached to the substrate S. Thus, the active layer 10 may be formed by the atomic layer deposition method in a state in which the inside of the chamber 100 or the substrate S has a low temperature of, for example, approximately 600° C. or less. In more detail, the active layer 10 may be formed by the atomic layer deposition method at a temperature of approximately 300° C. or more to approximately 550° C. or less. That is, the active layer 10 may be formed at a low temperature without forming the active layer 10 in a state in which the substrate is heated to a high temperature as in the related art. Thus, the substrate S, for example, the thin film or the active layer 10 formed on the substrate due to high heat may be prevented from being damaged.

In addition, the plasma may allow the thin film deposited on the substrate S to become crystalline by the reaction between the source gas and the reactant gas. More specifically, the polycrystalline active layer 10 may be formed. That is, in the forming of the active layer 10 by the atomic layer deposition method, the plasma may be generated after injecting the reactant gas, and thus, the crystalline or polycrystalline active layer 10 may be formed by the plasma.

In addition, the plasma may decompose impurities remaining in the chamber 100 to facilitate removal. Thus, contamination due to the impurities when the deposition film, that is, the active layer 10 is formed may be prevented or suppressed.

In the above, it has been described that the doping gas is injected after the source gas is injected. That is, it has been described that the source gas and the doping gas are divided into separate processes and then are injected. However, an exemplary embodiment is not limited thereto, and the source gas and the doping gas may be mixed to be injected. That is, the source gas and the doping gas may be mixed, and the mixed gas (hereinafter, a mixed gas) may be injected in the process of injecting the source gas. In this case, ‘the injection of the mixed gas—the generation of the plasma—the injection of the purge gas (primary purging)—the injection of the reactant gas—the injection of the purge gas (secondary purging)—the generation of the plasma’ may be used as one process cycle.

Also, in the above, it has been described that the plasma is generated after the finishing of the secondary purging or after injecting the reactant gas. However, an exemplary embodiment of the present disclosure is not limited thereto, and the hydrogen plasma may be generated in a process between the injection of the source gas and the injection of the reactant. More specifically, the hydrogen plasma may be generated between the process of injecting the source gas and the primary purging process. That is, ‘the injection of the source gas—the generation of the plasma—the injection of the purge gas (primary purging)—the injection of the reactant gas—the injection of the purge gas (secondary purging)’ may be used as one process cycle.

As another example, the hydrogen plasma may be generated between the primary purging process and the reactant gas injection process. Thus, ‘the injection of the source gas—the injection of the purge gas (primary purging)—the generation of the plasma—the injection of the reactant gas—the injection of the purge gas (secondary purging)’ may be defined as one process cycle.

As another example, the plasma may be generated in each of the process between the injection of the source gas and the injection of the reactant and after the process of injecting the reactant gas. That is, ‘the injection of the source gas—the generation of the plasma—the injection of the purge gas (primary purging)—the injection of the reactant gas—the injection of the purge gas (secondary purging)—the generation of the plasma’ may be defined as the process cycle, or ‘the injection of the source gas—the injection of the purge gas (primary purging)—the generation of the plasma—the injection of the reactant gas—the injection of the purge gas (secondary purging)—the generation of the plasma’ may be defined as the process cycle.

In the forming of the active layer 10 in the process cycle as described above, materials of the source gas and the reactant gas may be determined in accordance with the type of the active layer 10 to be formed.

The active layer 10 may be made of any one of a GaAs layer, an InP layer, an AlGaInP layer, an IGZO layer, an IZO layer, and a SiC layer. In this case, the source gas may be a gas including any one or two or more of Ga, In, Zn, and Si. That is, the source gas may be a gas including any one or two or more of a gas containing Ga, a gas containing In, a gas containing Al, Ga, and In (a gas containing AlGaIn), a gas containing In, Ga, and Zn (a gas containing IGZ), a gas containing In and Zn (a gas containing IZ), and a gas containing Si. In addition, the reactant gas may be a gas including one or two or more of As, P, O, and C. That is, the reactant gas may be a gas including any one or two or more of an As-containing gas, a P-containing gas, an O-containing gas, and a C-containing gas.

For example, when a GaAs layer is formed as the active layer 10, the gas containing Ga may be used as the source gas, and the gas containing As may be used as the reactant gas. In addition, when the InP layer is formed as the active layer 10, the gas containing In may be used as the source gas, and the gas containing P may be used as the reactant gas. As another example, when forming the AlGaInP layer as the active layer 10, the gas containing Al, the gas containing Ga, or the gas containing In may be used as the source gas, and the gas containing P may be used as the reactant gas. As another example, when forming the IGZO layer as the active layer 10, the gas containing In, the gas containing Ga, and the gas containing Zn may be used as the source gas, and the gas containing O may be used as the reactant gas. In addition, when the IZO layer is formed as the active layer 10, the gas containing In or the gas containing Zn may be used as the source gas, and the gas containing O may be used as the reactant gas. In addition, when the SiC layer is formed as the active layer 10, the gas containing Si may be used as the source gas, and the gas containing C may be used as the reactant gas.

Here, a gas containing trimethyl gallium (Ga(CH3)3) (TMGa) may be used as, for example, the Ga-containing gas, and a gas containing at least one of trimethyl indium (In(CH3)3) (TMIn) or diethylamino propyl dimethyl indium (DADI) may be used as, for example, the In-containing gas. In addition, a gas containing trimethylaluminum (A(CH3)3) (TMA) may be used as, for example, the Al-containing gas, and a gas containing at least one of diethyl zinc (Zn(C2H5)2) (DEZ) or dimethyl zinc (Zn(CH3)2)) (DEZ) may be used as the Zn-containing gas. In addition, a gas containing at least one of SiH4 and Si2H6 may be used as, for example, the Si-containing gas.

In addition, a gas containing any one of AsH3 and AsH4 may be used as the As-containing gas, and a gas containing, for example, phosphine (PH3) may be used as the P-containing gas. In addition, the O-containing gas may be oxygen, and the C-containing gas may be, for example, a gas containing SiH3CH3.

As described above, when forming the active layer 10 of the GaAs layer, the Ga-containing gas is used as the source gas, and when forming the active layer 10 of the InP layer, the In-containing gas is used as the source gas. In addition, when forming the active layer 10 of the SiC layer, the Si-containing gas is used as the source gas. Thus, when the active layer 10 is made of any one of a GaAs layer, an InP layer, and a SiC layer, the active layer 10 may be described as using one type of source gas.

As another example, when the active layer 10 of the AlGaInP layer is formed, three kinds of gases, i.e., the Al-containing gas, the Ga-containing gas, and the In-containing gas are used as the source gas. As another example, when the active layer 10 is formed with the IGZO layer, three kinds of gases, i.e., the In-containing gas, the Ga-containing gas, and the Zn-containing gas are used as the source gas. Thus, when the active layer 10 is formed as the AlGaInP layer or the IGZO layer, it may be described as using two or more kinds, i.e., a plurality of source gases.

In the forming of the active layer 10 by using or injecting the plurality of source gases, the active layer 10 may be formed by injecting the plurality of source gases mixed with the source gases. A detailed description of a method for mixing and injecting the plurality of source gases will be described later when the deposition device is described.

The doping gas may be injected after the source gas is injected or may be mixed with the source gas to be injected. Here, the doped gas may be determined in accordance with the type of the active layer 10 to be formed. For example, when forming the p-type active layer 10, a gas containing Mg may be used as the doping gas, and when forming the n-type active layer 10, a gas containing Si may be used as the doping gas. Here, a gas containing Cp2Mg may be used as the doping gas containing Mg, and a gas containing, for example, polysilane (H3Si—(SiH2)n-SiH3) may be used as the doping gas containing Si. In addition, the second doping gas may be one or a mixture of one or more of Si, In, Al, and Zn.

Then, the above-described process cycle is repeated a plurality of times to form the active layer 10. Here, in the process cycle performed initially or primarily to form the active layer 10, the process cycle may be performed without the process of injecting the doping gas. That is, the process cycle performed primarily to form the active layer 10 may be a process cycle of ‘the injection of the source gas—the injection of the purge gas (primary purging)—the injection of the reactant gas—the injection of the purge gas (secondary purging)—the generation of the plasma’. Here, the doping gas may be injected together when the source gas is injected, or the doping gas may not be separately injected. Also, the doping gas may be injected after the source gas is injected from the subsequent process, or the doping gas may be injected when injecting the source gas. Thus, when the active layer 10 is formed on the active layer 10, the thin film deposited by the primary process cycle is an undoped thin film, and the thin film deposited by the subsequent process cycle may be a doped thin film.

Of course, the active layer 10 may be formed by injecting the doping gas in the process cycle that is performed initially or primarily.

The active layer 10 may be provided in a stepped shape so that heights of the surface are different from each other as illustrated in FIG. 2. In other words, the active layer 10 may be described as including a first layer 11 formed on the top surface of the substrate S and a second layer 12 formed on a partial area of the first layer 11. Thus, a thickness of a region of the active layer 10, in which the second layer 12 is formed, may be thicker than those of other regions. In other words, the active layer 10 may be provided in a shape in which a height of an area, on which the second layer 12 is formed, is greater than that of a portion, at which only the first layer 11 is formed, that is, in a shape having a height difference.

The shape of the active layer 10 is not limited to be provided in the stepped shape as described above, and if well layers 20a and 20b are provided between the source electrodes 41a and 41b and the active layers 10a and 10b and between the drain electrodes 42a and 42b and the active layers 10a and 10b, respectively, each of the active layer 10 may be provided in any shape.

The first and second well layers 20a and 20b may be layers commonly referred to as well regions in the complementary metal oxide semiconductor device. Here, since the well regions are formed in the active layers 10a and 10b by being deposited through the atomic layer deposition method, respectively, the well regions will be referred to as the well layers 20a and 22 for convenience of description. The well layers 20a and 20b may be provided to be disposed between the source and drain electrodes and the active layer. More specifically, the first well layer 20a is provided between the first source electrode 41a and the first active layer 10a and between the first drain electrode 42a and the first active layer 10a, and the second well layer 20b is provided between the second source electrode 41b and the second active layer 10b and between the second drain electrode 42b and the second active layer 10b. Thus, the first well layer 20a is provided to be disposed between the first layer 11 of the first active layer 10a and the first source electrode 41a and between the first layer 11 and the first drain electrode 42a as illustrated in FIG. 2. In addition, the second well layer 20b is provided to be disposed between the first layer 11 of the second active layer 10b and the second source electrode 41b and between the first layer 11 and the second drain electrode 42b. In addition, the first and second well layers 20a and 20b may be formed through the atomic layer deposition method.

The first and second well layers 20a and 20b may be provided so that the same material as the active layer 10 is doped with n-type or p-type impurities. For example, when the first active layer 10a is provided in a p-type AlGaInP, the first well layer 20a may be prepared in an n-type by doping AlGaInP with an impurity, for example Si, and the second active layer 10b may be provided in an n-type AlGaInP, the second well layer 20b may be prepared in a p-type by doping AlGaInP with an impurity, for example, Mg. Thus, the first well layer 20a may be described as an n-type AlGaInP layer doped with Si, and the second well layer 20b may be described as a p-type AlGaInP layer doped with Mg.

Hereinafter, a method of forming the first and second well layers 20a and 20b using the atomic layer deposition method will be described. Here, since only doping materials of the first well layer 20a and the second well layer 20b are different from each other, and their formation methods are similar to each other, the first and second well layers 20a and 20b are collectively referred to a well layer 20 (20a and 20b), and thus, the formation method thereof will be described.

The well layer 20 may be formed through the atomic layer deposition method. That is, the well layer 20 may be formed by using ‘the injection of the source gas—the injection of the purge gas (primary purging)—the injection of the reactant gas—the injection of the purge gas (secondary purging)’ as the process cycle. In this case, the source gas, the doping gas, the reactant gas, and the purge gas, which are injected to form the well layer 20, may be the same as the gas used to form the active layer 10.

In addition, the doping gas for forming the well layer 20 may be mixed with the source gas and injected. That is, the source gas and the doping gas may be mixed, and the mixed gas may be injected in the process of injecting the source gas. In this case, ‘the injection of the mixed gas—the generation of the plasma—the injection of the purge gas (primary purging)—the injection of the reactant gas—the injection of the purge gas (secondary purging)’ may be used as one process cycle for forming the well layer 20.

In addition, in the forming of the well layer 20, the plasma may be generated when the reactant gas is injected, or the plasma may be additionally generated after the secondary purging. Also, the plasma generated after the secondary purging may be a hydrogen plasma.

The well layer 20 formed as described above functions as source and drain regions in the complementary metal oxide semiconductor device. That is, each of the first and second well layers 20a and 20b disposed under the first and second source electrodes 41a and 41b functions as a source of the complementary metal oxide semiconductor device, and each of the first and second well layers 20a and 20b disposed under the first and second drain electrodes 42a and 42b functions as a drain of the complementary metal oxide semiconductor device.

The gate insulating layer 30 (30a and 30b) may be disposed on the active layer 10 (10a and 10b). That is, the first gate insulating layer 30a may be disposed on the first active layer 10a, and the second gate insulating layer 30b may be disposed on the second active layer 10b. More specifically, in a vertical direction, the first gate insulating layer 30a may be provided to be disposed between the first gate electrode 50a and the first active layer 10a, and the second gate insulating layer 30b may be provided to be disposed between the second gate electrode 50b and the second active layer 10b. In addition, in a width direction, the first gate insulating layer 30a may be provided to be disposed between the first source electrode 41a and the first drain electrode 42a, and the second gate insulating layer 30b may be provided to be disposed between the second source electrode 41b and the second drain electrode 42b. In addition, the first gate insulating layer 30a may be provided so that an edge of a bottom surface thereof is disposed on a pair of first well layers 20a, and a remaining portion is disposed on the first active layer 10a, and the second gate insulating layer 30b may be provided so that an edge of a bottom surface thereof is disposed on a pair of second well layers 20b, and a remaining portion is disposed on the second active layer 10b. Thus, the edge of the first gate insulating layer 30a and edges of the pair of first well layers 20a may be provided to overlap each other, and the edge of the second gate insulating layer 30b and edges of the pair of second well layers 20b may be provided to overlap each other.

Each of the first and second gate insulating layers 30a and 30b may be made of a high-k thin film having a dielectric constant greater than that of silicon dioxide (SiO₂). More specifically, each of the first and second gate insulating layers 30a and 30b may be made of one or a combination of two or more of aluminum oxide (AlOₓ), titanium oxide (TiOₓ), magnesium oxide (MgOₓ), zirconium oxide (ZrOₓ), silicon hafnium oxide (HfSiOₓ), and lanthanum silicon oxide (LaSiOₓ), where ‘x’ may be 1 to 3. Of course, the first and second gate insulating layers 30a and 30b are not limited to the above-described examples and may be made of various other high-dielectric materials having a dielectric constant greater than silicon dioxide (SiO₂).

The source electrodes 41a and 41b and the drain electrodes 42a and 42b may be disposed on the active layers 10a and 10b and the well layers 20a and 20b with the gate insulating layers 30a and 30b and the gate electrodes 50a and 50b therebetween. That is, each of the first source electrode 41a and the first drain electrode 42a may be disposed on the pair of first well layers 20a with the first gate insulating layer 30a and the first gate electrode 50a therebetween. In other words, the first source electrode 41a may be disposed at one side of the first gate insulating layer 30a, and the first drain electrode 42a may be disposed at the other side of the first gate insulating layer 30a. In addition, the second source electrode 41b and the second drain electrode 42b may be disposed on the pair of second well layers 20b with the second gate insulating layer 30b and the second gate electrode 50b therebetween, respectively. That is, the second source electrode 41b may be disposed at one side of the second gate insulating layer 30b, and the second drain electrode 42b may be disposed at the other side of the second gate insulating layer 30b.

Each of the first and second source electrodes 41a and 41b and the first and second drain electrodes 42a and 42b may be made of a material including a metal, for example, may be made of at least one of Ti or Au. In addition, the first and second source electrodes 41a and 41b and the first and second drain electrodes 41 and 42 may be formed through, for example, the chemical vapor deposition (CVD) method, the metal organic chemical vapor deposition (MOCVD) method, the atomic layer deposition (ALD) method, sputtering deposition method, or the like.

The gate electrodes 50a and 50b may be disposed on the gate insulating layers 30a and 30b, respectively. In other words, the first gate electrode 50a may be disposed on the first gate insulating layer 30a so as to be disposed between the first source electrode 41a and the first drain electrode 42a, and the second gate electrode 50b may be disposed on the second gate insulating layer 30b so as to be disposed between the second source electrode 41b and the second drain electrode 42b. In this case, each of the first and second gate electrodes 50a and 50b may be made of a material including a metal, for example, may be made of a material including at least one of Ti or Au. In addition, the first and second gate electrodes 50a and 50b may be formed through a sputtering deposition method.

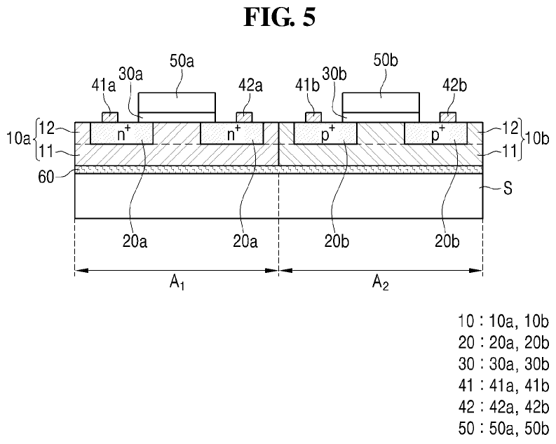

FIG. 4 is a conceptual view illustrating a modified example in which a buffer layer is disposed between the active layer and the substrate. FIG. 5 is a view illustrating an example of the complementary metal oxide semiconductor device in accordance with a modified example of the exemplary embodiment.

Referring to FIGS. 4 and 5, a buffer layer 60 may be disposed between the substrate S and each of the first and second active layers 10a and 10b. In addition, as illustrated in FIG. 5, the complementary metal oxide semiconductor device in accordance with the modified example may include a buffer layer 60 disposed between the substrate S and each of the first and second active layers 10a and 10b. That is, the complementary metal oxide semiconductor device in accordance with the modified example is different from the complementary metal oxide semiconductor device in accordance with the foregoing embodiment in that the buffer layer 60 is disposed between each of the first and second active layers 10a and 10b and the substrate S, but other configurations are the same.

The buffer layer 60 may be a layer that is formed first on the substrate S before the first and second active layers 10a and 10b are formed, i.e., may be a seed layer that assists the first and second active layers 10a and 10b formed through the atomic layer deposition method to be more effectively crystallized. In other words, when the first and second active layers 10a and 10b is formed through the atomic layer deposition method, the buffer layer 60 may be a seed layer that additionally assists in crystallization of the first and second active layers 10a and 10b in addition to the crystallization by the hydrogen plasma. The buffer layer 60 may be made of AlN and may be formed through an atomic layer deposition method, the chemical vapor deposition method, or the like.

When the first and second active layers 10a and 10b are deposited on the crystalline buffer layer 60 through the atomic layer deposition method, the first and second active layers 10a and 10b may be grown in a crystal direction of the underlying buffer layer 60. Thus, the crystalline, more particularly, the polycrystalline active layers 10a and 10b may be more easily formed.

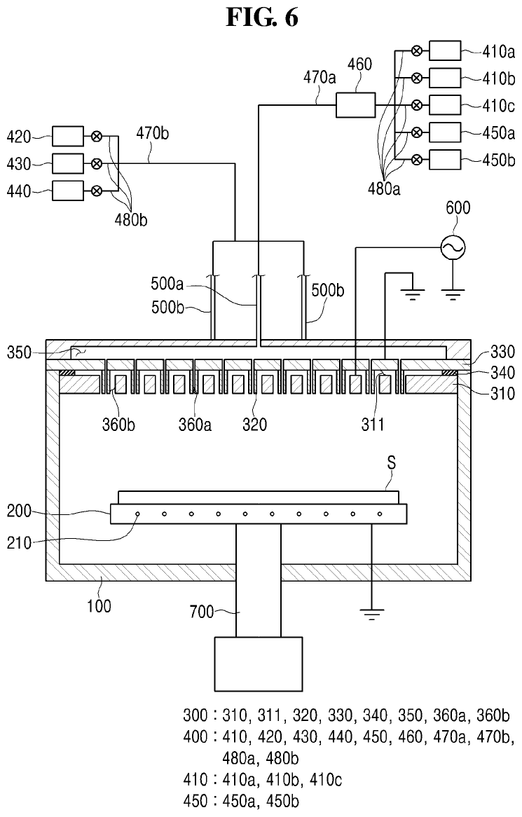

FIG. 6 is a schematic view illustrating a deposition device used in the method for manufacturing the power semiconductor device in accordance with an exemplary embodiment.

The deposition device may be a device for depositing a thin film through an atomic layer deposition (ALD) method. Here, the deposition device may be a device for forming at least the first and second active layers 10a and 10b among components of the power semiconductor device, for example, the complementary metal oxide semiconductor device. Also, the deposition device may be a device for forming the first and second active layers 10a and 10b and the first and second well layers 20a and 20b.

As illustrated in FIG. 6, the deposition device may include a chamber 100, a support 200 installed in the chamber 100 to support a substrate S, an injection part 300 disposed to face the support 200 and inject for injecting a gas for processes (hereinafter, referred to as a process gas) into the chamber 100, a gas injection part 400 configured to provide the process gas to the injection part 300, first and second gas supply tubes 500a and 500b connected to the injection part 300 so that the first and second gas supply tubes 500a and 500b have paths different from each other and configured to supply the gas provided from the gas supply part 400 to the injection part 300, and an RF power supply part 600 configured to apply power so that plasma is generated in the chamber 100.

In addition, the deposition device may further include a driving part 700 configured to operate the support 200 in at least one of elevating and rotating operations and an exhaust part (not shown) installed to be connected to the chamber 100.

The chamber 100 may include an inner space in which a thin film is disposed on the substrate S loaded into the chamber 100. For example, a cross-section thereof may have a shape such as a quadrangular shape, a pentagonal shape, or a hexagonal shape. Of course, a shape of the inside of the chamber 100 may be changed in various manners, the shape of the inside of the chamber 100 may be provided to correspond to that of the substrate S.

The support 200 is installed inside the chamber 100 to face the injection part 300 and supports the substrate S loaded into the chamber 100. A heater 210 may be provided inside the support 200. Thus, when the heater 210 is operated, the substrate S seated on the support 200 and the inside of the chamber 100 may be heated.

In addition, a separate heater may be provided inside the chamber 100 or outside the chamber 100 in addition to the heater 210 provided in the support 200 as a means configured to heat the substrate S or the inside of the chamber 100.

The injection part 300 may include a first plate 310 having a plurality of holes (hereinafter, referred to as holes 311) arranged in an extension direction of the support 200 and defined to be spaced apart from each other and disposed to face the support 200 inside the chamber 100, a nozzle 320 provided so that at least a portion thereof is inserted into each of the plurality of holes 311, and a second plate 330 installed to be disposed between an upper wall inside the chamber 100 and the first plate 310 inside the chamber 100.

In addition, the injection part 300 may further include an insulating part 340 disposed between the first plate 310 and the second plate 330.

Here, the first plate 310 may be connected to the RF power supply part 600, and the second plate 330 may be grounded. In addition, the insulating part 340 may serve to prevent electrical connection between the first plate 310 and the second plate 330.

The first plate 310 may have a plate shape extending in the extension direction of the support 200. In addition, the plurality of holes 311 are provided in the first plate 310, and each of the plurality of holes 311 may be provided to pass through the first plate 310 in a vertical direction. In addition, the plurality of holes 311 may be arranged in the extension direction of the first plate 310 or the support 200.

Each of the plurality of nozzles 320 may have a shape extending in the vertical direction, have a path through which a gas passes is provided therein, and have opened upper and lower ends. In addition, each of the plurality of nozzles 320 may be installed so that at least a lower portion thereof is inserted into the hole 311 provided in the first plate 310, and an upper portion thereof is connected to the second plate 330. Thus, the nozzle 320 may be described as a shape protruding downward from the second plate 330.

An outer diameter of the nozzle 320 may be provided to be less than an inner diameter of the hole 311. In addition, when the nozzle 320 is installed to be inserted into the hole 311, an outer circumferential surface of the nozzle 320 may be installed to be spaced apart from a peripheral wall of the hole 311 (i.e., an inner wall of the first plate 310). Thus, the inside of the hole 311 may be divided into an outer space of the nozzle 320 and an inner space of the nozzle 320.

In the inner space of the hole 311, the path in the nozzle 320 is a path through which the gas provided from the first gas supply tube 500a moves and is injected. In addition, in the inner space of the hole 311, the outer space of the nozzle 320 is a path through which the gas provided from the second gas supply tube 500b moves and is injected. Thus, hereinafter, the path within the nozzle 320 is referred to as a first path 360a, and the space outside the nozzle 320 within the hole 311 is referred to as a second path 360b.

The second plate 330 may be installed so that a top surface thereof is spaced apart from the upper wall of the chamber 100, and a bottom surface thereof is spaced apart from the first plate 310. Thus, empty spaces may be provided between the second plate 330 and the first plate 310 and between the second plate 330 and the upper wall of the chamber 100, respectively.

Here, an upper space of the second plate 330 may be a space (hereinafter, a diffusion space 350) in which the gas provided from the first gas supply tube 500a is diffused to move and may communicate with an upper opening of each of the plurality of nozzles 320. In other words, the diffusion space 350 is a space communicating with the plurality of first paths 360a. Thus, the gas passing through the first gas supply tube 500a may be diffused in the extension direction of the second plate 330 in the diffusion space 350 and then may pass through the plurality of first paths 360a and be injected downward.

In addition, a gun drill (not shown), which is a path through which gas moves, may be provided inside the second plate 330, and the gun drill may be connected to the second gas supply tube 500b and provided to communicate with the second path 360b. Thus, the gas provided from the second gas supply tube 500b may be injected toward the substrate S through the gun drill of the second plate 330 and the second path 360b.

The gas supply part 400 provides a gas that is necessary for depositing a thin film by an atomic layer deposition method. The gas supply part 400 may include a source gas storage part 410 in which a source gas is stored, a reactant gas storage part 420 in which a reactant gas reacting with the source gas is stored, a purge gas storage part 430 in which a purge gas is stored, a first transfer tube 470a installed to connect the source gas storage part 410 to the first gas supply tube 500a, and a second transfer tube 470b installed to the reactant gas storage part 420 and the purge gas storage part 430 to the second gas supply tube 500b.

Here, the purge gas stored in the purge gas storage part 430 may be, for example, an N2 gas or an Ar gas.

In addition, the gas supply part 400 may include a gas storage part for generating plasma, in which the gas supplied in a process of generating plasma inside the chamber 100 (hereinafter, referred to as plasma generating gas) is stored after the reactant gas is injected or after the secondary purging 440. Here, the gas for generating the plasma may be, for example, a hydrogen gas.

In addition, the gas supply part 400 may include a doping gas storage part 450, in which a doping gas is stored, and a mixing part 460 installed in the first transfer tube 470a to mix a plurality of types of gases.

In addition, the gas supply part 400 may include a plurality of first connection tubes 480a connecting each of the source gas storage part 410 and the doping gas storage part 450 to the first transfer tube 470a, a valve installed in each of the plurality of first connection tubes 480a, a plurality of second connection tubes 480b connecting each of the reactant gas storage 420, the purge gas storage 430, and the gas storage 440 for generating the plasma to the second transfer tube 470b, and a valve installed in each of the plurality of second connection tubes 480b.

The source gas storage part 410 may be provided in plurality, and different types of source gases may be stored in the plurality of source gas storage parts 410 (410a, 410b, and 410c), respectively. Also, the first connection tube 480a may be connected to each of the plurality of source gas storage parts 410a, 410b, and 410c, and the first connection tubes 480a respectively connected to the plurality of source gas storage parts 410a, 410b, and 410c may be connected to the first transfer tube 470a.

The doping gas storage part 450 may be provided in plurality, and different types of doping gases may be stored in the plurality of doping gas storage parts 450 (450a and 410b), respectively. Also, the first connection tube 480a may be connected to each of the plurality of doping gas storage parts 450a and 410b, and the first connection tubes 480a respectively connected to the plurality of source gas storage parts 450a and 410b may be connected to the first transfer tube 470a.

The mixing part 460 may be a means that mixes the gas provided from the plurality of source gas storage parts 410a, 410b, and 410c or mixes the gas provided from at least one of the plurality of source gas storage parts 410a, 410b, and 410c with the gas provided from at least one of the doping gas storage parts 450a and 450b. The mixing part 460 may be provided to have an inner space in which the gas is capable of being mixed. In addition, the mixing part 460 may be installed to connect the first connection tube 480a connected to each of the plurality of source gas storage parts 410a, 410b, and 410c and the plurality of doping gas storage parts 450a and 450b to the first transfer tube 470a. Thus, the plurality of types of gases introduced into the mixing part 460 may be mixed in the mixing part 460 and then transferred to the first gas supply tube 500a through the first transfer tube 470a.

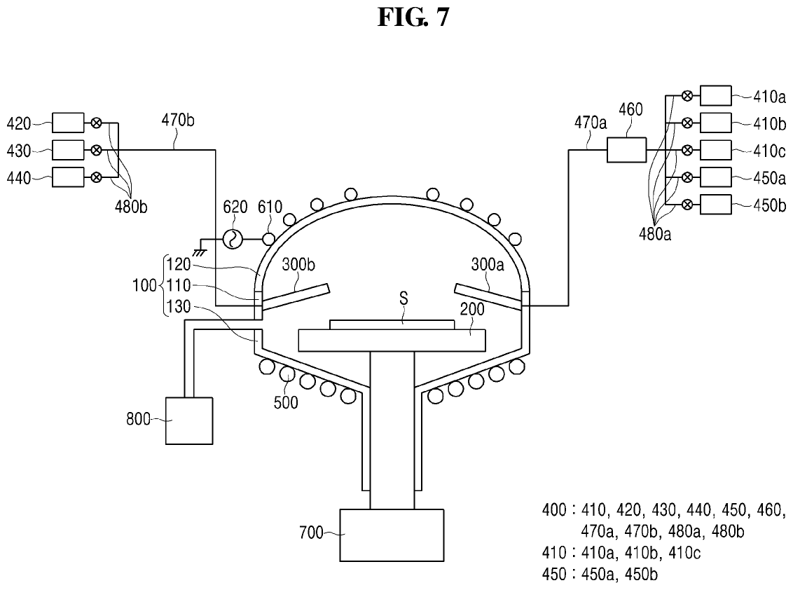

FIG. 7 is a schematic view illustrating another example of the deposition device used in the method for manufacturing the power semiconductor device in accordance with an exemplary embodiment. The deposition device for forming at least one of the first and second active layers 10a and 10b and the first and second well layers 20a and 20b of the power semiconductor device in accordance with the embodiment is not limited to the device illustrated in FIG. 5, and thus, the deposition device illustrated in FIG. 7 may be used.

Referring to FIG. 7, the deposition device may include a chamber 100, a support 200 installed in the chamber to support a substrate S, first and second gas injection parts 300a and 300b, each of which is installed in the chamber to face the support 200, a gas supply part 400 configured to supply a process gas to each of the first and second gas injection parts 300a and 300b, an antenna 610 provided with a coil for inducing electric fields in the chamber 100 to generate plasma, and a power supply part 620 connected to the antenna 610.

In addition, the deposition device may include a heating part 500 installed to face the support 200, a driving part 700 configured to elevate or rotate the support 200, and an exhaust part 800 configured to exhaust gases and impurities inside the chamber 100.

The chamber 100 may have a tubular shape having an inner space, in which a thin film is formed on the substrate S loaded into the chamber, for example, a dome shape as illustrated in FIG. 7. More specifically, the chamber 100 may include a chamber body 110, an upper body 120 installed on an upper portion of the chamber body 110, and a lower body 130 installed on a lower portion of the chamber body 110. The chamber body 110 may have a tubular shape having opened upper and lower portions, the upper body 120 may be installed to cover an upper opening of the chamber body 110, and the lower body 130 may be installed to cover a lower opening of the chamber body 110. In addition, the upper body 120 may have a dome shape having an inclined surface that increases in height toward a center in a width direction. In addition, the lower body 130 may have a dome shape having an inclined surface that decreases in height toward a center in a width direction. The chamber 100, that is, each of the chamber body 110, the upper body 120, and the lower body 130 may be made of a transparent material that allows light to pass therethrough and may be made of, for example, quartz.

The gas supply part 400 may be provided in the same configuration as that described with reference to FIG. 6. That is, the gas supply part 400 may include a source gas storage part 410 in which a source gas is stored, a reactant gas storage part 420 in which a reactant gas reacting with the source gas is stored, a purge gas storage part 430 in which a purge gas is stored, a first transfer tube 470a installed to connect the source gas storage part 410 to the first gas injection part 300a, and a second transfer tube 470b installed to the reactant gas storage part 420 and the purge gas storage part 430 to the second gas injection part 300b.

In addition, the gas supply part 400 may include a gas storage part for generating plasma, in which the gas supplied in a process of generating plasma inside the chamber 100 (hereinafter, referred to as plasma generating gas) is stored after the reactant gas is injected or after the secondary purging 440. Here, the gas for generating the plasma may be, for example, a hydrogen gas.

In addition, the gas supply part 400 may include a doping gas storage part 450, in which a doping gas is stored, and a mixing part 460 installed in the first transfer tube 470a to mix a plurality of types of gases.

In addition, the gas supply part 400 may include a plurality of first connection tubes 480a connecting each of the source gas storage part 410 and the doping gas storage part 450 to the first transfer tube 470a, a valve installed in each of the plurality of first connection tubes 480a, a plurality of second connection tubes 480b connecting each of the reactant gas storage 420, the purge gas storage 430, and the gas storage 440 for generating the plasma to the second transfer tube 470b, and a valve installed in each of the plurality of second connection tubes 480b.

The antenna 610 may be installed on an upper portion of the upper body 120 of the chamber 100. In this case, the antenna 610 may be provided in a spiral wound with a plurality of turns or may have a configuration including a plurality of circular coils arranged in a concentric circle shape and connected to each other. Of course, the antenna 610 is not limited to the spiral coil or the concentric circular coil, and various types of antennas having different shapes may be applied.

One end of both ends of the antenna 610 may be connected to a power supply part 620, and the other end may be connected to a ground terminal. Therefore, when power, for example, RF power is applied to the antenna 610 through the power supply part 620, a gas injected into the chamber 100 is ionized or discharged to generate plasma in the chamber 100.

The heating part 500 is a means that heats the inside and the support 200 of the chamber 100 and may be installed outside the chamber 100. More specifically, the heating part 500 may be installed so that at least a portion of a lower side outside the chamber 100 faces the support 200. The heating part 500 may be a means including a plurality of lamps, and the plurality of lamps may be installed to be arranged in a width direction of the support 200. Also, the plurality of lamps may include lamps such as halogen that emits radiant heat.

Hereinafter, a method of manufacturing the power semiconductor device in accordance with an exemplary embodiment will be described with reference to FIGS. 2 and 3. Here, the description will be made using the deposition device of FIG. 6, and a complementary metal oxide semiconductor device will be described as an example.

First, a heater 210 provided in a support 200 operates to heat the support 200. Here, the heater operates so that a temperature of the support 200 or the substrate S to be seated on the support 200 is, for example, approximately 500° C. to approximately 520° C.

Next, the substrate S, for example, a substrate S made of SiC is loaded into the chamber 100 so as to be seated on the support 200. In this case, one or more substrates S may be provided on the support 200. Thereafter, when the substrate S seated on the support 200 reaches a target process temperature, for example, approximately 500° C. to approximately 520° C., the first and second active layers 10 are formed on the substrate S.

In this case, the first and second active layers 10a and 10b are formed using an atomic layer deposition method. The atomic layer deposition is performed in order of an injection of a source gas, an injection of a doping gas, an injection of a purge gas (primary purging), an injection of a reactant gas, and an injection of the purge gas (secondary purging). Here, plasma is generated inside the chamber 100 after the secondary purging. That is, the process cycle of forming the first and second active layers 10a and 10b by the atomic layer deposition method may be a cycle of ‘the injection of the source gas—the injection of the doping gas—the injection of the purge gas (primary purging)—the injection of the reactant gas—the injection of the purge gas (secondary purging)—generation of plasma’. Then, the above-described process cycle is repeated a plurality of times to form the first and second active layers 10a and 10b, each of which has a target thickness.

Hereinafter, the method for forming the first and second active layers 10a and 10b by injecting a process gas into the chamber 100 using an injection part 300 and a gas supply part 400 will be described in more detail. Here, a case in which a p-type first active layer 10a made of AlGaInP and an n-type second active layer 10b made of AlGaInP are formed will be described as an example.

In addition, it will be described that either one of the first active layer 10a and the second active layer 10b, for example, the first active layer 10a is first formed, and then the second active layer 10b is formed.

For the shape of the first active layer 10a, a mask that exposes a first area A1 of the substrate S and shields a second area A2 is disposed above the substrate S seated on the support 200. Here, the mask may be a shadow mask in which an opening is provided in an area corresponding to the first area A1 of the substrate S.

When the mask is disposed at the upper side of the substrate S, the source gas is injected into the chamber 100. For this, each of an Al-containing gas stored in a first source gas storage part 410, a Ga-containing gas stored in a second source gas storage part 410, and an In-containing gas stored in a third source gas storage part 410 is supplied into a mixing part 460. Thus, three kinds of source gases, that is, the Al-containing gas, the Ga-containing gas, and the In-containing gas are mixed in the mixing part 460.

The mixed source gas is introduced into a diffusion space 350 in the injection part 300 through a first transfer tube 470a and a first gas supply tube 500a. Then, the mixed source gas is diffused in the diffusion space 350 and then passes through a plurality of nozzles 320, that is, a plurality of first paths 360a and is injected toward the substrate S. Then, the injected source gas passes through the opening of the mask and is adsorbed onto the first area A1 of the top surface of the substrate S.

When the injection of the source gas is stopped or finished, the first doping gas is supplied through the first doping gas storage part 450a to inject the first doping gas into the chamber 100. In this case, the first doping gas may be a gas containing Mg, and more specifically, a gas containing Cp2Mg may be used. The first doping gas discharged from the first doping gas storage part 450a may pass through the first connection tube 480a, the first transfer tube 470a, and the first gas supply tube 500a and then may be injected downward through the first path 360a. The injected first doping gas may be adsorbed onto the first area A1 of the top surface of the substrate S after passing through the opening of the mask.

When the injection of the first doping gas is stopped or finished, the purge gas is provided through the purge gas storage part 430 to inject the purge gas into the chamber 100 (primary purging). Here, the purge gas discharged from the purge gas storage part 430 may pass through the second connection tube 480b, the second transfer tube 470b, and the second gas supply tube 500b and then be injected downward through a second path 360b.

Next, the reactant gas, for example, a P-containing gas, is provided from the reactant gas storage part 420 and injected into the chamber 100. In this case, the reactant gas may be injected into the chamber 100 through the same path as the purge gas. That is, after passing through the second connection tube 480b, the second transfer tube 470b, and the second gas supply tube 500b, the reactant gas may be injected downward through the second path 360b. The injected reactant gas passes through the opening of the mask toward the first area A1 of the substrate S. In addition, the reactant gas that has reached the first area A1 may react with the source gas adsorbed on the first area A1 to generate a reactant, that is, AlGaInP. Then, the reactant is accumulated or deposited on the substrate S to form a thin film made of AlGaInP on the substrate S. At this time, an AlGaInP thin film doped with Mg by the first doping gas, that is, a p-type AlGaInP thin film is formed.

When the reactant gas is injected into the chamber 100 in this manner, an RF power supply part 600 may operate to apply RF power to the first plate 310. When the RF power is applied to the first plate 310, plasma may be generated in the second path 360b in the injection part 300 and in a space between the first plate 310 and the support 200.

When the reactant gas injection is stopped, the purge gas is supplied through the purge gas storage part 430 to inject the purge gas into the chamber 100 (secondary purging). In this case, by-products of the reaction between the source gas and the reactant gas may be discharged to the outside of the chamber 100 by the secondary purging.

When the secondary purging is finished, a gas such as a hydrogen gas is provided from the gas storage part 440 for generating the plasma, and the RF power is turned on to apply the RF power to the first plate 310. Thus, the plasma using the hydrogen gas, that is, hydrogen plasma is generated in the chamber 100.

The first active layer 10a is formed on the first area A1 of the substrate S through the process cycle that is performed in order of ‘the injection of the source gas, the injection of the first doping gas, the injection of the purge gas (primary purging), the injection of the reactant gas, the injection of the purge gas (secondary purging), and the generation of the plasma’ as described above. In this case, the first active layer 10a may be provided as an AlGaInP thin film doped with Mg, that is, a p-type AlGaInP thin film.

Also, the process cycle performed in the order of ‘the injection of the source gas, the injection of the first doping gas, the injection of the purge gas (primary purging), the injection of the reactant gas, the injection of the purge gas (secondary purging), and the generation of the plasma’ as described above may be repeated a plurality of times. In addition, the number of times of the process cycle to be performed may be determined in accordance with the target thickness of the first active layer 10a.

As described above, the plasma may be generated in the chamber 100 after injecting the reactant gas or the secondary purging, the first active layer 10a may be formed on the substrate S even at a low temperature of approximately 600° C. or less. In addition, more specifically, the polycrystalline first active layer 10a may be formed.

When the first active layer 10a having the target thickness is formed, the second active layer 10b is formed next. To this end, a mask for exposing the second area A2 of the substrate S and shielding the first area A1 is disposed at the upper side of the substrate S on which the first active layer 10a is formed. Here, the mask may be a shadow mask in which an opening is provided in an area corresponding to the second area A2 of the substrate S.

When the mask is disposed at the upper side of the substrate S, the second active layer 10b is formed by depositing a thin film in the same manner as when the first active layer 10a is formed. However, the thin film is deposited using a different doping gas than when the first active layer 10a is formed. In other words, the thin film is deposited using the first doping gas containing Mg and the second doping gas containing another element. Here, the process cycle performed in the order of ‘the injection of the source gas, the injection of the doping gas, the injection of the purge gas (primary purging), the injection of the reactant gas, the injection of the purge gas (secondary purging), and the generation of the plasma’ is repeated a plurality of times to form the second well layer 10b. Here, the source gas, the purge gas, and the reactant gas may be the same as when the first active layer 10a is formed. In addition, the second doping gas is provided from the second doping gas storage part 450b, and a gas containing Si, for example, a gas containing polysilane (H₃Si—(SiH₂)n-SiH₃) may be used.

As described above, the second active layer 10b is formed on the second area A2 of the substrate S through the process cycle that is performed in order of ‘the injection of the source gas, the injection of the second doping gas, the injection of the purge gas (primary purging), the injection of the reactant gas, the injection of the purge gas (secondary purging), and the generation of the plasma’. In this case, the second active layer 10b may be made of an AlGaInP thin film doped with Si, that is, an n-type AlGaInP thin film.

In addition, the second doping gas may be one or a mixture of one or more of Si, In, Al, and Zn.

In addition, the above-described process cycle including the process of injecting the second doping gas may be repeated a plurality of times. In this case, the number of times of the process cycle to be performed may be determined in accordance with the target thickness of the second active layer 10b.

When the first and second active layers 10a and 10b, each of which has a target thickness, are formed, a portion of each of the first and second active layers 10a and 10b is etched. For example, the first and second active layers 10a and 10b having predetermined thicknesses are etched in an outer area of a central area in a width direction of each of the first and second active layers 10a and 10b. For this, for example, a mask for closing the central area of each of the first and second active layers 10a and 10b and opening a portion of the outer area of the central area is provided, and the mask is disposed above the first and second active layers 10a and 10b. In addition, the first and second active layers 10a and 10b exposed to the opening area are partially etched by injecting an etching gas from the upper side of the first and second active layers 10a and 10b. Here, the etching is performed so that the first and second active layers 10a and 10b facing the opening area of the mask remains to have the target thickness. At this time, the etching gas may be used for the etching by applying at least one of SF₆, Cl₂, CF₄, or O₂ or a combination of the two gases and plasma.

Due to this etching, a groove or well recessed from a top surface toward an opposite side of the top surface may be provided in each of the first and second active layers 10a and 10b. That is, a pair of first grooves spaced apart from each other in the width direction may be provided in the first active layer 10a, and a pair of second grooves spaced apart from each other in the width direction may be provided in the second active layer 10b. Here, the pair of first grooves provided in the first active layer 10a may be provided at positions facing the first source electrode 41a and the first drain electrode 42a to be formed later, and the pair of second grooves provided in the second active layer 10b may be provided at positions facing the second source electrode 41b and the second drain electrode 42b to be formed later. Due to this etching, each of the first and second active layers 10a and 10b may be provided in a form including the first layer 11 formed on a top surface of the substrate S and a second layer 12 formed outside the groove on the first layer 11. Thus, each of the first and second active layers 10a and 10b may be provided in a shape in which a height of an area, on which the second layer 12 is formed, is greater than that of a portion, at which only the first layer 11 is formed, that is, in a shape having a height difference.

As described above, the process of etching a portion of each of the active layers 10a and 10b may be performed in a device that is separated from the deposition device illustrated in FIG. 6. In addition, the etching device may be a device connected to the deposition device in situ.

When the etching is finished, the first well layer 20a is formed in the first layer 11 of the first active layer 10a, and the second well layer 20b is formed in the first layer 11 of the second active layer 10b. In other words, the first well layer 20a is formed in the pair of first grooves provided in the first active layer 10a by the etching, and the second well layer 20b is formed in the pair of second grooves provided in the second active layer 10b by the etching. The first and second well layers 21 and 22 may be formed through, for example, an atomic layer deposition method and may be formed using the same deposition device as when the active layers 10a and 10b are formed.

Hereinafter, the method for forming the first and second well layers 21 and 22 will be described, and the method of forming the first and second well layers 21 and 22 using the deposition device illustrated in FIG. 6 will be described. In this case, a case in which the first well layer 20a is provided as the n-type AlGaInP layer, and the second well layer 20b is provided as the p-type AlGaInP layer will be described as an example.

First, a method of forming the first well layer 20a will be described. An opening is provided in an area facing the pair of first grooves provided in the first active layer 10a, and a mask with the remaining closed portion is disposed at the upper side of the substrate S.

Next, the source gas is injected into the chamber 100. For this, each of an Al-containing gas stored in a first source gas storage part 410, a Ga-containing gas stored in a second source gas storage part 410, an In-containing gas stored in a third source gas storage part 410, and an Si-containing gas stored in a doping gas storage part 450 is supplied into a mixing part 460. Thus, the Al-containing gas, the Ga-containing gas, the In-containing gas, and the Si-containing gas are mixed in the mixing part 460. The mixed gases are injected toward the substrate S by passing through the first transfer tube 470a, the first gas supply tube 500a and the first path 360a of the injection part 300. The injected gases pass through the opening of the mask to reach the pair of first grooves provided in the first active layer 10a and then are adsorbed into the first grooves.

When the injection of the source gas is stopped or finished, the second doping gas is supplied through the second doping gas storage part 450b to inject the second doping gas into the chamber 100. In this case, an Si-containing gas may be the second doping gas, more particularly, a gas containing polysilane (H₃Si—(SiH₂)n-SiH₃) may be used as the Si-containing gas. The second doping gas discharged from the second doping gas storage part 450b may pass through the first connection tube 480a, the first transfer tube 470a, and the first gas supply tube 500a and then may be injected downward through the first path 360a. The injected second doping gas may reach the pair of first grooves provided in the first active layer 10a after passing through the opening of the mask.

Thereafter, the purge gas is supplied from the purge gas storage part 430, and the purge gas is injected into the chamber 100 through the second path 360b of the injection part 300 (primary purging).

Next, a reactant gas, for example, a P-containing gas is provided from the reactant gas storage part 420 and injected into the chamber 100 through the second path 360b of the injection part 300. Here, RF power may be applied to the first plate 310 to generate plasma.

When the reactant gas is injected, a reaction between the source gas adsorbed onto the substrate S and the reactant gas may occur to generate a reactant, that is, AlGaInP. Here, since the second doping gas is injected after the source gas is injected, the reactant becomes an AlGaInP thin film doped with Si. Thus, the first well layer 20a made of the n-type AlGaInP thin film may be formed in the first groove of the first active layer 10a. In other words, the first well layer 20a made of an n-type AlGaInP thin film may be formed in a pair of well regions provided in the first active layer 10a by the etching. In other words, the first well layer 20a made of an n-type AlGaInP thin film may be formed on the first layer 11 of the first active layer 10a.

In addition, the second doping gas may be one or a mixture of one or more of Si, In, Al, and Zn.

When the reactant gas injection is finished, the purge gas is supplied from the purge gas storage part 430 to inject the purge gas into the chamber 100 (secondary purging).

When the secondary purge is finished, the process of generating plasma in the chamber 100 may be added. That is, a gas, for example, the hydrogen gas is supplied from the gas storage part 440 for generating the plasma, the hydrogen gas is injected into the chamber 100, and the RF power is applied to the first plate 310. Thus, the plasma using the hydrogen gas, that is, hydrogen plasma is generated in the chamber 100.

Thereafter, the process cycle performed in the order of ‘the injection of the source gas, the injection of the second doping gas, the injection of the purge gas (primary purging), the injection of the reactant gas, the injection of the purge gas (secondary purging), and the generation of the plasma’ is repeated a plurality of times to form the first well layer 22a having a target thickness.

When the first well layer 20a having the target thickness is formed, the second well layer 20b is formed next. For this, an opening is provided in an area facing the pair of second grooves provided in the second active layer 10b, and a mask with the remaining closed portion is disposed at the upper side of the substrate S.

When the mask is disposed at the upper side of the substrate S, the second well layer 20b is formed by depositing a thin film in the second groove in the same manner as when the second well layer 20a is formed. However, the thin film is deposited using a different doping gas than when the first well layer 20a is formed. That is, the thin film is deposited using the second doping gas containing Si and the first doping gas containing another element. Thereafter, the process cycle performed in the order of ‘the injection of the source gas, the injection of the first doping gas, the injection of the purge gas (primary purging), the injection of the reactant gas, the injection of the purge gas (secondary purging), and the generation of the plasma’ is repeated a plurality of times to form the second well layer 20b having a target thickness.

Here, the source gas, the purge gas, and the reactant gas may be the same as when the first well layer 20a is formed. In addition, the first doping gas is provided from the first doping gas storage part 450a, and a gas containing Mg, for example, a gas containing Cp2Mg may be used.

The second well layer 20b is formed in the pair of second grooves provided in the second active layer 10b through the process cycle that is performed in order of ‘the injection of the source gas, the injection of the first doping gas, the injection of the purge gas (primary purging), the injection of the reactant gas, the injection of the purge gas (secondary purging), and the generation of the plasma’. In this case, the second well layer 20b may be provided as an AlGaInP thin film doped with Mg, that is, a p-type AlGaInP thin film.

In addition, the above-described process cycle including the process of injecting the first doping gas may be repeated a plurality of times, and the number of times of the process cycle to be performed may be determined in accordance with the target thickness of the second well layer 20b.

In the above description, the plasma is generated after the secondary purging in the forming of the first and second well layers 20a and 20b. However, an exemplary embodiment is not limited thereto, and the process of generating the plasma after the secondary purging may be omitted.

When the first and second well layers 20a and 20b, each of which has the target thickness, are formed, the gate insulating layers 30a and 30b are formed to be disposed on the first and second active layers 10a and 10b and the first and second well layers 20b. That is, the first gate insulating layer 30a is formed on the first active layer 10a and the first well layer 20a, and the second gate insulating layer 30b is formed on the second active layer 10b and the second well layer 20b. Here, an edge of a bottom surface of the first gate insulating layer 30a is disposed on an upper portion of each of the pair of first well layers 20a, and the remaining portion is disposed on an upper portion of the first active layer 10a between the pair of first well layers 20a. In addition, an edge of a bottom surface of the second gate insulating layer 30b is disposed on an upper portion of each of the pair of second well layers 20b, and the remaining portion is disposed on an upper portion of the second active layer 10b between the pair of second well layers 20b. Here, each of the first and second gate insulating layers 30a and 30b may be made of, for example, Al₂O₃ and may be formed through any one of a chemical vapor deposition method, an organometallic chemical vapor deposition method, and an atomic layer deposition method.

Next, first and second source electrodes 41a and 41b and first and second drain electrodes 42a and 42b are formed. That is, the first source electrode 41a is formed on one of the pair of first well layers 20a, and the first drain electrode 42a is formed on the other first well layer 20a. In addition, the second source electrode 41b is formed on one of the pair of second well layers 20b, and the second drain electrode 42b is formed on the other second well layer 20b.

Also, gate electrodes 50a and 50b are formed on the first and second gate insulating layers 30a and 30b, respectively. Here, the gate electrodes 50a and 50b may be prepared using the same material and the same method as the source and drain electrodes 41a, 41b, 42a, and 42b. For example, each of the gate electrodes 50a and 50b may be made of at least one of Ti or Au, and may be formed through the sputtering deposition method.

As described above, in accordance with the method for manufacturing the power semiconductor device in accordance with the exemplary embodiment, the active layer 10 (10a and 10b) may be formed at the low temperature. Therefore, the substrate S or the thin film formed on the substrate may be prevented from being damaged by the high-temperature heat. In addition, the power or time required for heating the substrate S to form the active layer 10 may be saved, and the overall process time may be shortened.

In addition, the active layer 10 may be crystallized to be formed. That is, the crystallized active layer 10 may be formed while forming the active layer at the low temperature.

### INDUSTRIAL APPLICABILITY

In accordance with the exemplary embodiments, the active layer may be formed at the low temperature. Thus, the substrate or the thin film formed on the substrate may be prevented from being damaged by the high-temperature heat. In addition, the power or time required for heating the substrate to form the active layer may be saved, and the overall process time may be shortened.

In addition, the active layer may be crystallized to be formed. That is, the crystallized active layer may be formed while forming the active layer at the low temperature.

What is claimed is:

1. A method for manufacturing a power semiconductor device, which comprises forming an active layer comprising a first active layer and a second active layer, which are doped with impurities different from each other, on an SiC substrate,
wherein the forming of the active layer comprises:
preparing the SiC substrate comprising a first area and a second area;
sequentially injecting a source gas mixed with a first doping gas, a purge gas, a reactant gas, and a purge gas onto the first area of the SiC substrate to form the first active layer; and
sequentially injecting a source gas mixed with a second doping gas, a purge gas, a reactant gas, and a purge gas onto the second area of the SiC substrate to form the second active layer,
wherein the second doping gas and the first doping gas comprise elements different from each other, respectively.

2. A method for manufacturing a power semiconductor device, which comprises forming an active layer comprising a first active layer and a second active layer, which are doped with impurities different from each other, on an SiC substrate,
wherein the forming of the active layer comprises:
preparing the SiC substrate comprising a first area and a second area;
sequentially injecting a source gas, a first doping gas, a purge gas, a reactant gas, and a purge gas onto the first area of the SiC substrate to form the first active layer; and
sequentially injecting a source gas, a second doping gas, a purge gas, a reactant gas, and a purge gas onto the second area of the SiC substrate to form the second active layer,
wherein the second doping gas and the first doping gas comprise elements different from each other, respectively.

3. The method of claim 1 or 2, wherein the source gas comprises one or two or more of Ga, In, Zn, and Si.

4. The method of claim 1 or 2, wherein the reactant gas comprises one or two or more of As, P, O, and C.

5. The method of claim 1, wherein the forming of the first and second active layers comprises repeatedly performing one process cycle, which is performed in order of the injection of the source gas, the injection of the purge gas, the injection of the reactant gas, and the injection of the purge gas.

6. The method of claim 2, wherein the forming of the first active layer comprises repeatedly performing one process cycle, which is performed in order of the injection of the source gas, the injection of the first doping gas, the injection of the purge gas, the injection of the reactant gas, and the injection of the purge gas, and
the forming of the second active layer comprises repeatedly performing one process cycle, which is performed in order of the injection of the source gas, the injection of the second doping gas, the injection of the purge gas, the injection of the reactant gas, and the injection of the purge gas.

7. The method of claim 5 or 6, wherein the forming of the first and second active layers comprises at least one of generating plasma after the injecting of the reactant gas or generating plasma between the injecting of the source gas and the injecting the reactant gas.

8. The method of claim 7, wherein the generating of the plasma comprises injecting a hydrogen gas.

9. The method of claim 1 or 2, further comprising, before the forming of the first and second active layers, forming a crystalline buffer layer on the SiC substrate.

10. The method of claim 9, wherein the buffer layer is made of AIN.

11. The method of claim 1 or 2, wherein one doping gas of the first and second doping gases contains Mg, and
the other doping gas contains at least one of Si, In, Al, or Zn.

12. A method for manufacturing a power semiconductor device, the method comprising:
preparing an SiC substrate comprising a first area and a second area, wherein a first conductive type first active layer is formed on the first area; and
sequentially injecting a source gas, a purge gas, a reactant gas, and a purge gas onto the second area to form a second conductive type second active layer,
wherein the first conductive type and the second conductive type are different from each other and, and each of the first conductive type and the second conductive type comprises one of an n-type and a p-type.

13. The method of claim 12, wherein the first active layer is formed by sequentially injecting the source gas, the purge gas, the reactant gas, and the purge gas, and
the source gas injected in the forming of the first and second active layers comprises one or two or more of Ga, In, Zn, and Si.

14. The method of claim 12, wherein the reactant gas injected in the forming of the first and second active layers comprises one or two or more of As, P, O, and C.
